(19) United States
(12) Patent Application Publication
(10) Pub. No.: US 2025/0142874 A1
(43) Pub. Date: May 1, 2025

(54) SEMICONDUCTOR DEVICE HAVING VERTICAL CHANNEL STRUCTURE AND MANUFACTURING METHOD OF VERTICAL CHANNEL STRUCTURE

(71) Applicant: Samsung Electronics Co., Ltd., Suwon-si (KR)

(72) Inventors: Changhyun KIM, Suwon-si (KR); Kyung-Eun BYUN, Suwon-si (KR); Minsu SEOL, Suwon-si (KR); Junyoung KWON, Suwon-si (KR); Huije RYU, Suwon-si (KR); Eunkyu LEE, Suwon-si (KR); Yeonchoo CHO, Suwon-si (KR)

(73) Assignee: Samsung Electronics Co., Ltd., Suwon-si (KR)

(21) Appl. No.: 18/660,936

(22) Filed: May 10, 2024

(30) Foreign Application Priority Data
Oct. 30, 2023 (KR) 10-2023-0146989

(51) Int. Cl. H01L 29/78; H01L 27/092; H01L 29/10; H01L 29/66

(52) U.S. Cl. CPC H10D 30/63; H10D 30/025; H10D 62/235; H10D 84/85

(57) ABSTRACT

Provided is a semiconductor device including a substrate, a first vertical channel, a spacer, and a second vertical channel. The first vertical channel may have a sheet shape extending in a direction perpendicular to a surface of the substrate. The spacer may be provided at an end of the first vertical channel in an extension direction. The second vertical channel may be aligned with the first vertical channel on the spacer and have a sheet shape extending in a vertical direction.

### CROSS-REFERENCE TO RELATED APPLICATION

This application is based on and claims priority under 35 U.S.C. § 119 to Korean Patent Application No. 10-2023-0146989, filed on Oct. 30, 2023, in the Korean Intellectual Property Office, the disclosure of which is incorporated by reference herein in its entirety.

### BACKGROUND

Various example embodiments relate to a semiconductor device having a vertical channel structure and/or a manufacturing method of the vertical channel structure.

According to the increased integration degree of semiconductor devices, various structures have been suggested to reduce a plane area occupied by each unit device. A transistor is or corresponds to a semiconductor device with an electric switching function and is employed in various integrated circuit (IC) devices including one or more of memories, driving ICs, logic devices, etc. To increase the integration degree of IC devices, a space occupied by a transistor has been significantly reduced. Due to this, the channel length of a transistor has been decreased, and/or the thickness of layers included in the transistor has been reduced. Accordingly, research to reduce the size of the transistor while maintaining the desired performance has been conducted.

### SUMMARY

Provided is a semiconductor device having a vertical channel transistor structure to improve the integration degree.

Alternatively or additionally provided is a manufacturing method of the vertical channel structure.

Additional aspects will be set forth in part in the description which follows and, in part, will be apparent from the description, or may be learned by practice of various example embodiments.

According to some example embodiments, a semiconductor device includes a substrate, a first vertical channel having a sheet shape extending from the substrate in a first direction perpendicular to a surface of the substrate, a spacer at an end of the first vertical channel in the first direction, and a second vertical channel aligned with the first vertical channel on the spacer and having a sheet shape extending in the first direction.

Alternatively or additionally according to various example embodiments, a manufacturing of a vertical channel structure includes forming a first channel material layer having a sheet shape by growing a first channel material in a vertical direction on a substrate, reducing a height of the first channel material layer by etching the first channel material layer, forming a second channel material layer having a sheet shape by growing a second channel material in the vertical direction from an upper portion of the first channel material layer, and forming an oxide layer by oxidizing an interface area of the first channel material layer and the second channel material layer.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a schematic perspective view of a semiconductor device according to some example embodiments;

FIG. 2 is a cross-sectional view of the semiconductor device of FIG. 1 taken along line D12-D12′, according to some example embodiments;

FIG. 3 is a cross-sectional view of the semiconductor device of FIG. 1 taken along line D13-D13′, according to some example embodiments;

FIG. 4 is a schematic plan view of a semiconductor device according to some example embodiments;

FIG. 5 is a schematic side view of a semiconductor device according to some example embodiments;

FIGS. 6A to 6J are diagrams each illustrating an example of a manufacturing method of a vertical channel structure; and

FIGS. 7 and 8 are conceptual diagrams each schematically illustrating a device architecture applicable to an electronic apparatus according to some example embodiments.

### DETAILED DESCRIPTION

Reference will now be made in detail to various embodiments, examples of which are illustrated in the accompanying drawings, wherein like reference numerals refer to like elements throughout. In this regard, variously described embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, various example embodiments will be described in detail with reference to the accompanying drawings. In the drawings, like reference numerals in the drawings denote like elements, and sizes of components in the drawings may be exaggerated for clarity and convenience of explanation. Meanwhile, embodiments described below are provided only as an example, and thus can be embodied in various forms.

It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described.

The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations.

Moreover, the terms “part,” “module,” etc. refer to a unit processing at least one function or operation, and may be implemented by a hardware, a software, or a combination thereof.

The connecting lines, or connectors shown in the various figures presented are intended to represent exemplary functional relationships and/or physical or logical couplings between the various elements, and thus it should be noted that many alternative or additional functional relationships, physical connections or logical connections may be present in a practical device.

The use of any and all examples, or exemplary language provided herein, is intended merely to better illuminate technical ideas and does not pose a limitation on the scope of embodiments unless otherwise claimed.

In the following example embodiments, a first direction D1 refers to a direction perpendicular to a substrate. A second direction D2 and a third direction D3 respectively refer to two directions perpendicular to each other in a plane perpendicular to the first direction D1.

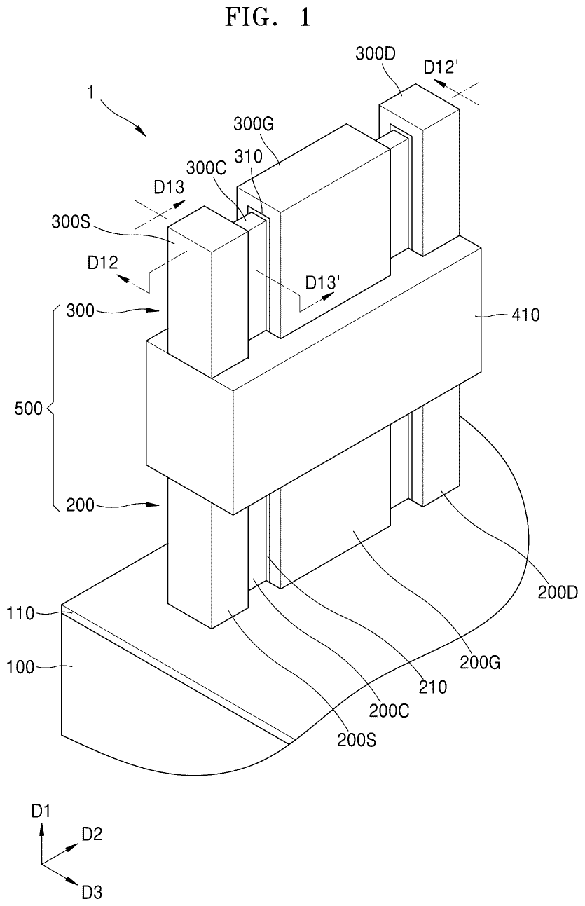

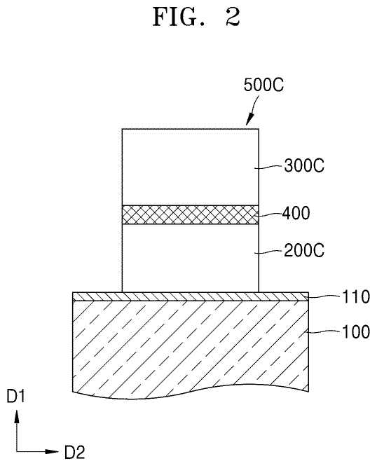

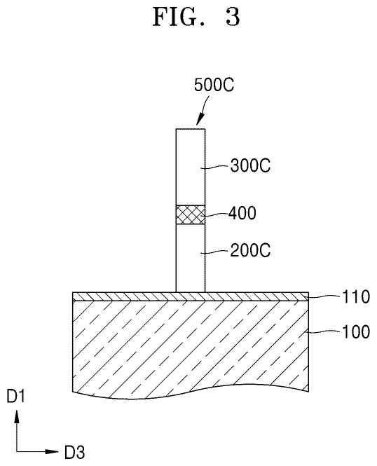

FIG. 1 is a schematic perspective view of a semiconductor device 1 according to some example embodiments. FIG. 2 is a cross-sectional view of the semiconductor device 1 of FIG. 1 taken along line D12-D12′, according to some example embodiments. FIG. 3 is a cross-sectional view of the semiconductor device 1 of FIG. 1 taken along line D13-D13′, according to some example embodiments. FIGS. 2 and 3 show components related to a channel structure, and an electrode structure is omitted.

Referring to FIGS. 1 to 3, the semiconductor device 1 may include a substrate 100 and a vertical channel structure 500C formed on the substrate 100. The vertical channel structure 500C may include a first vertical channel 200C and a second vertical channel 300C which are aligned and extend, for example, in the first direction D1. The vertical channel structure 500C may include a spacer 400 arranged between the first vertical channel 200C and the second vertical channel 300C. A first source electrode 200S, a first drain electrode 200D, and a first gate electrode 200G may correspond to the first vertical channel 200C. A second source electrode 300S, a second drain electrode 300D, and a second gate electrode 300G may correspond to the second vertical channel 300C. According to this, a vertical channel transistor structure 500 including a first vertical channel transistor 200 and a second vertical channel transistor 300 which are aligned in the vertical direction, e.g., in the first direction D1, may be formed. The vertical channel transistor structure 500 may form or may correspond to a unit device of the semiconductor device 1.

The substrate 100 may be or may include an insulating substrate. The substrate 100 may be or include a semiconductor substrate on which an insulating layer 110 is formed. The semiconductor substrate may include, for example, one or more of Si, Ge, SiGe, or group III-V semiconductor materials, etc. The substrate 100 may be or include, for example, a silicon substrate on which a silicon oxide is formed; however, example embodiments are not limited thereto. The substrate 100 may be doped or may be undoped.

The first vertical channel 200C may have a sheet shape extending in the first direction D1, which is the vertical direction, and may extend from a surface of the substrate 100. The spacer 400 may be arranged at end of the first vertical channel 200C in the first direction D1. The second vertical channel 300C may be aligned with the first vertical channel 200C on the spacer 400. The second vertical channel 300C may have a sheet shape extending in the first direction D1 from the spacer 400. Each of the first vertical channel 200C and the second vertical channel 300C may have a width in the second direction D2 and a thickness in the third direction D3. The first vertical channel 200C and the second vertical channel 300C may have the same width; however, example embodiments are not limited thereto. The first vertical channel 200C and the second vertical channel 300C may have the same thickness; however, example embodiments are not limited thereto. The vertical channel structure 500C having a fin shape (or, a nano-sheet shape) may be formed by the first vertical channel 200C, the second vertical channel 300C, and the spacer 400.

The first vertical channel 200C and the second vertical channel 300C may independently or concurrently include a two-dimensional (2D) semiconductor material. The 2D semiconductor material may include, for example, one or more of a transition metal dichalcogenide (TMD) material, graphene, black phosphorus, amorphous boron nitride, or phosphorene.

For example, the first vertical channel 200C and the second vertical channel 300C may include a TMD material. The first vertical channel 200C and the second vertical channel 300C may use a 2D material, for example, a TMD material to implement a short channel length when the semiconductor device 1 is applied as a field effect transistor (FET). The channel length or the electrical channel length refers to a length of a channel in a direction in which a source electrode and a drain electrode are apart from each other. According to the recent tendency of miniaturization of electronic apparatuses, the channel length has decreased. When the channel length decreases, issues due to short channel effects may occur. To prevent or reduce the impact of and/or probability of such issues and to effectively reduce the channel length, it may be advantageous to maintain a thin channel thickness. For example, the thinner the thickness of the channel is, the shorter the minimum implementable channel length may be. The 2D semiconductor material, for example, a TMD material may have excellent electrical characteristics, and even when the 2D semiconductor material has a nano-scale thickness, the characteristics may not change significantly, and high mobility may be maintained. In some cases, the TMD material is or includes a 2D material formed by van der Waals force and has an advantage of retaining device characteristics even in a single layer. The TMD material may have a mono-layer or multi-layer structure. Each layer of the TMD material included in the channel may have a thickness of atomic level (e.g., several tens of angstroms of thickness).

For example, the thickness of the first vertical channel 200C and the second vertical channel 300C may be 10 nm or less, 5 nm or less, or 3 nm or less. However, the thickness of the first vertical channel 200C and the second vertical channel 300C is not limited thereto and may be thinner. The width of the first vertical channel 200C and the second vertical channel 300C may be 5 nm or less, 4 nm or less, or 3 nm or less. However, example embodiments are not limited thereto. The thinner the thickness of the first vertical channel 200C and the second vertical channel 300C is, the shorter the length of the first vertical channel 200C and the second vertical channel 300C may be. For example, the first vertical channel 200C and the second vertical channel 300C may independently or concurrently include, for example, a TMD material having one to ten layers.

The TMD material may include, for example, one transition metal from among Mo, W, Nb, V, Ta, Ti, Zr, Hf, Tc, and Re and one chalcogen element from among S, Se, and Te. The TMD material may be represented by, for example, MX₂ where M represents a transition metal, and X represents a chalcogen element. For example, M may be Mo, W, Nb, V, Ta, Ti, Zr, Hf, Tc, Re, etc., and X may be S, Se, T, etc. Accordingly, the TMD material may include MoS2, MoSe2, MoTe2, WS2, WSe2, WTe2, ZrS2, ZrSe2, HfS2, HfSe2, NbSe2, ReSe2, etc.

However, the aforementioned materials are just an example, and other materials may be used as a TMD material. For example, the TMD material may not be represented by MX₂. In some cases, for example, the TMD material may include CuS which is a compound of Cu, a transition metal, and S, a chalcogen element. The TMD material may be chalcogenide material including a non-transition metal. The non-transition metal may include, for example, Ga, In, Sn, Ge, Pb, etc. In this case, the TMD material may include a compound of a non-transition metal such as Ga, In, Sn, Ge, Pb, etc. and a chalcogen element such as S, Se, and Te. For example, the TMD material may include SnSe2, GaS, GaSe, GaTe, GeSe, In2Se3, InSnS2, etc.

In some example embodiments, the first vertical channel 200C and the second vertical channel 300C may include different depositable semiconductor materials from each other. For example, at least one of or only one of the first vertical channel 200C and the second vertical channel 300C may include polysilicon. The polysilicon may be undoped, or may be doped.

In some example embodiments, the first vertical channel 200C and the second vertical channel 300C may include an oxide semiconductor of which conductivity may be controlled through doping. For example, the oxide semiconductor may include a metal oxide semiconductor.

The first vertical channel 200C and the second vertical channel 300C may have different conductivity types from each other. For example, the first vertical channel 200C may be a p-channel, and the second vertical channel 300C may be an n-channel. Or, the first vertical channel 200C may be an n-channel, and the second vertical channel 300C may be a p-channel. The first vertical channel 200C and the second vertical channel 300C may have the same conductivity type. For example, the first vertical channel 200C and the second vertical channel 300C may have an n-channel/n-channel structure or a p-channel/p-channel structure. To this end, the first vertical channel 200C and the second vertical channel 300C may be doped with a p-type dopant or an n-type dopant, when necessary or by design. The p-type dopant and the n-type dopant may be doped to the first vertical channel 200C and the second vertical channel 300C through ion implantation and/or chemical doping.

In some cases, the first vertical channel 200C and/or the second vertical channel 300C may be counterdoped. For example, a doping concentration of n-type dopants in the first vertical channel 200C and/or the second vertical channel 300C may be greater than, e.g., much greater than, a doping concentration of p-type dopants in the first vertical channel, and may accordingly be an n-channel. Alternatively or additionally, a doping concentration of p-type dopants in the first vertical channel 200C and/or the second vertical channel 300C may be greater than, e.g., much greater than, a doping concentration of n-type dopants in the first vertical channel 200C and/or the second vertical channel 300C, and may accordingly be a p-cannel.

The spacer 400 may electrically separate the first vertical channel 200C from the second vertical channel 300C. For example, the spacer 400 may include an oxide. For example, the spacer 400 may include an oxide of a material forming the first vertical channel 200C and the second vertical channel 300C. In some example embodiments, when the first vertical channel 200C and the second vertical channel 300C include a TMD material, the spacer 400 may include a transition metal oxide. Although the TMD material has an advantage of having a stable structure without a dangling bond, due to the absence of dangling bond, it is difficult to deposit a dielectric material thereon. The TMD material has characteristics that a dielectric layer is formed only in a defect. As there is a defect in an interface of the first vertical channel 200C and the second vertical channel 300C which include a TMD material, when the first vertical channel 200C and the second vertical channel 300C are oxidized, the interface area of the first vertical channel 200C and the second vertical channel 300C may be oxidized, and a transition metal oxide may be formed. The spacer 400 may be implemented by or may include a transition metal oxide. In some example embodiments, when the first vertical channel 200C and the second vertical channel 300C include polysilicon, the spacer 400 may include a silicon oxide.

The first source electrode 200S may be electrically connected to one end of the first vertical channel 200C in the second direction D2. The first drain electrode 200D may be electrically connected to another end of the first vertical channel 200C in the second direction D2. As used herein, “source” and “drain” electrodes may perform functions consistent with a source, respectively, drain, of a transistor; however, example embodiments are not limited thereto, and in some cases, a drain electrode may perform functions of a source of a transistor while a source electrode may perform functions of a drain of a transistor. The first source electrode 200S and the first drain electrode 200D may be in edge contact or surface contact with the first vertical channel 200C. The first gate electrode 200G may face the first vertical channel 200C with a first gate insulating film 210 arranged therebetween. The first gate insulating film 210 may insulate the first gate electrode 200G from the first vertical channel 200C. The second source electrode 300S may be electrically connected to one end of the second vertical channel 300C in the second direction D2. The second drain electrode 300D may be electrically connected to another end of the second vertical channel 300C in the second direction D2. The second source electrode 300S and the second drain electrode 300D may be in edge contact or surface contact with the second vertical channel 300C. The second gate electrode 300G may face the second vertical channel 300C with a second gate insulating film 310 arranged therebetween. The second gate insulating film 310 may insulate the second gate electrode 300G from the second vertical channel 300C.

The first and second source electrodes 200S and 300S, the first and second drain electrodes 200D and 300D, and the first and second gate electrodes 200G and 300G may independently or concurrently include a metal material or a conductive oxide. The metal material may independently or concurrently include, for example, at least one selected from Au, Ti, TIN, TaN, W, Mo, WN, Pt, and Ni. The conductive oxide may include, for example, indium tin oxide (ITO), indium zinc oxide (IZO), etc. The first and second source electrodes 200S and 300S, the first and second drain electrodes 200D and 300D, and the first and second gate electrodes 200G and 300G may independently or concurrently include polysilicon or single-crystal silicon. The first and second source electrodes 200S and 300S, the first and second drain electrodes 200D and 300D, and the first and second gate electrodes 200G and 300G may independently or concurrently be doped. The first and second gate insulating films 210 and 310 may independently or concurrently include, for example, a metal oxide dielectric material. The metal oxide dielectric material may be, for example, an oxide of Al, La, Ti, Zr, Hf, Mg, Ge, Y, Lu, or Sr.

An insulating layer 410 may insulate the first source electrode 200S, the first drain electrode 200D, and the first gate electrode 200G from each other, and insulate the second source electrode 300S, the second drain electrode 300D, and the second gate electrode 300G from each other. A material of the insulating layer 410 is not particularly limited.

Accordingly, the first and second vertical channel transistors 200 and 300 having a vertical forksheet FET structure and aligned in the vertical direction, e.g., the first direction D1 may, be formed. When the first vertical channel 200C and the second vertical channel 300C have different conductivity types from each other, the vertical channel transistor structure 500 may form or correspond to a complementary field effect transistor (CFET). In some cases, the vertical channel transistor structure 500 may correspond to an inverter; example embodiments are not limited thereto.

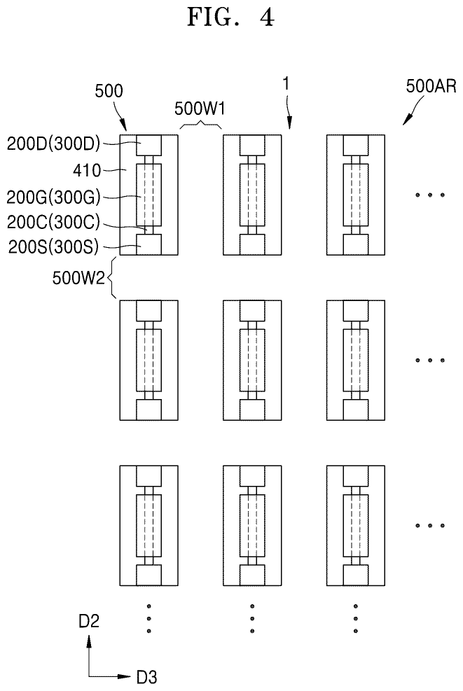

FIG. 4 is a schematic plan view of the semiconductor device 1 according to various example embodiments. Referring to FIG. 4, the semiconductor device 1 may include a vertical channel transistor array 500AR. The vertical channel transistor array 500AR may include a plurality of first vertical channels 200C and a plurality of second vertical channels 300C arranged in a 2D manner on a plane perpendicular to the first direction D1. For example, the vertical channel transistor array 500AR may include a plurality of vertical channel transistor structures 500 arranged in a 2D manner on a plane perpendicular to the first direction D1. As the vertical channel transistor structure 500 has a vertical forksheet FET structure, a plurality of vertical channel transistor structures 500 may be arranged in a given area. Accordingly, an integration degree of the semiconductor device 1 may increase. A wiring structure may be arranged in areas 500W1 and 500W2 between the vertical channel transistor structures 500. By combining a capacitor with each of the vertical channel transistor structures 500, the semiconductor device 1 may be implemented as a memory device having a 1T1C structure. In this case, a plurality of word liens extending in the second direction D2 may be provided in the area 500W1, and a plurality of bit lines extending in the third direction D3 may be provided in the area 500W2.

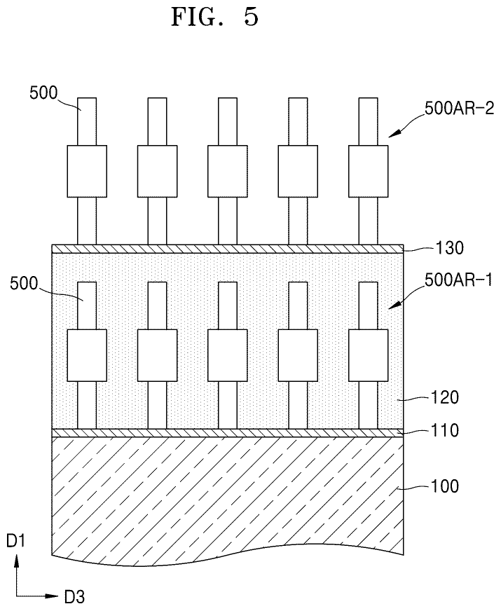

FIG. 5 is a schematic side view of the semiconductor device 1 according to some example embodiments. Referring to FIG. 5, the semiconductor device 1 may include a plurality of vertical channel transistor arrays stacked in the vertical direction, e.g., the first direction D1, with an isolation layer 120 arranged therebetween. As some example embodiments, FIG. 5 illustrates two vertical channel transistor arrays (500AR-1 and 500AR-2). The vertical channel transistor arrays 500AR-1 may be formed on the substrate 100. The isolation layer 120 may cover the vertical channel transistor arrays 500AR-1. An insulating layer 130 may be provided on the isolation layer 120, and the vertical channel transistor arrays 500AR-2 may be stacked on the insulating layer 130. The insulating layer 130 may be identical to, for example, the insulating layer 110. The isolation layer 120 may include an insulating material. By such structure, the integration degree of the semiconductor device 1 may be further improved.

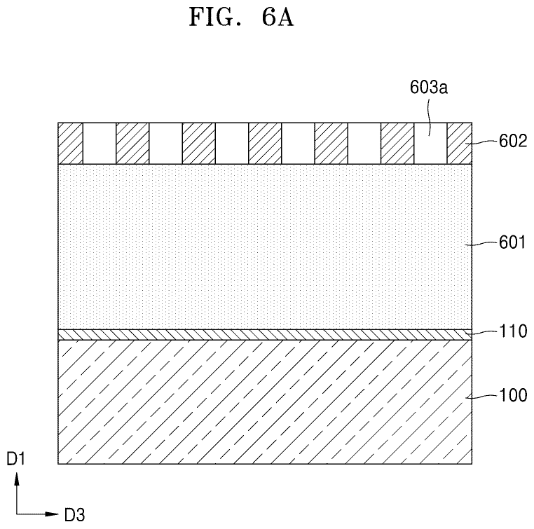

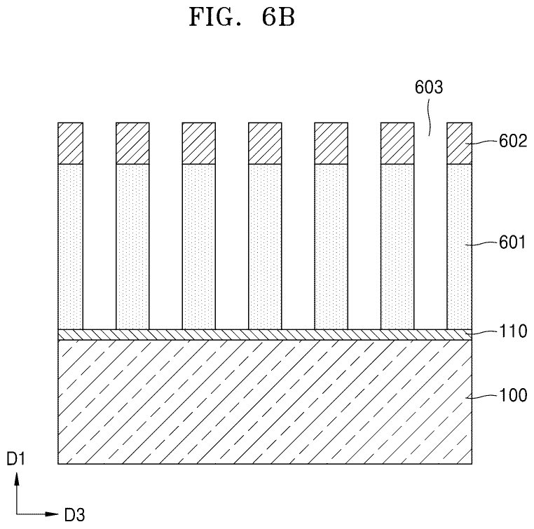

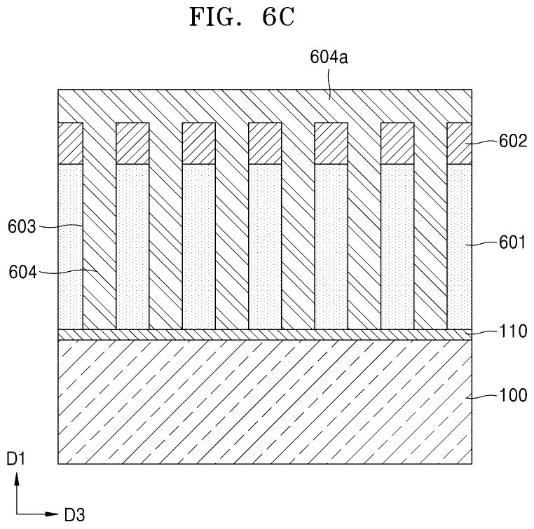

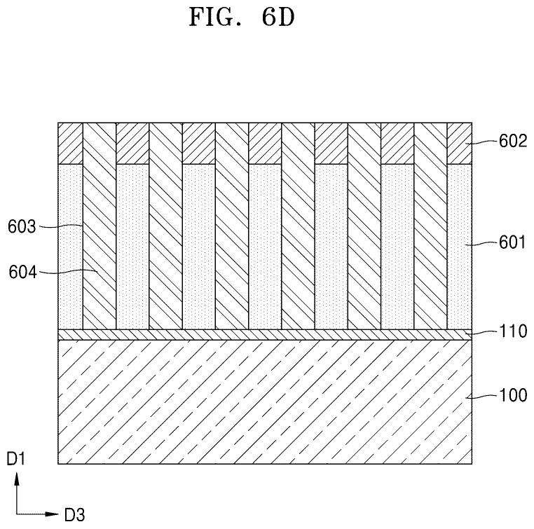

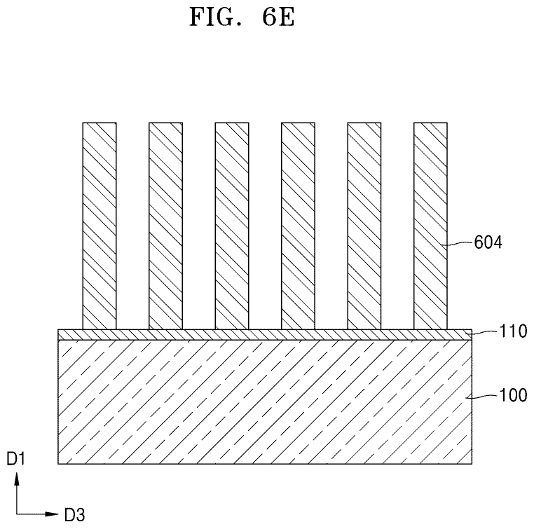

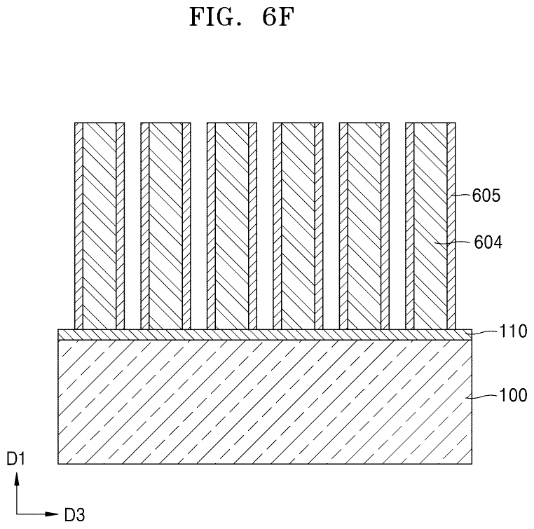

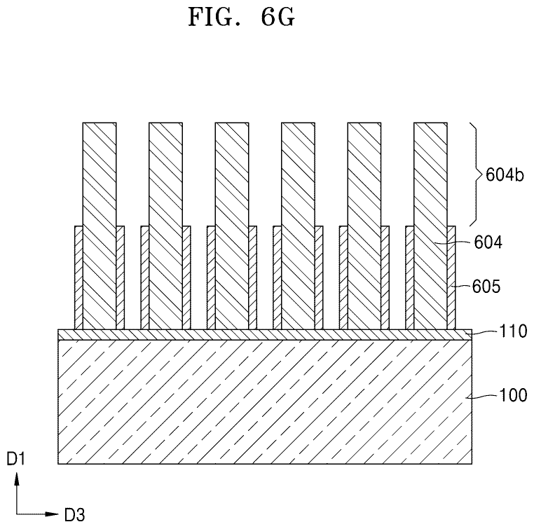

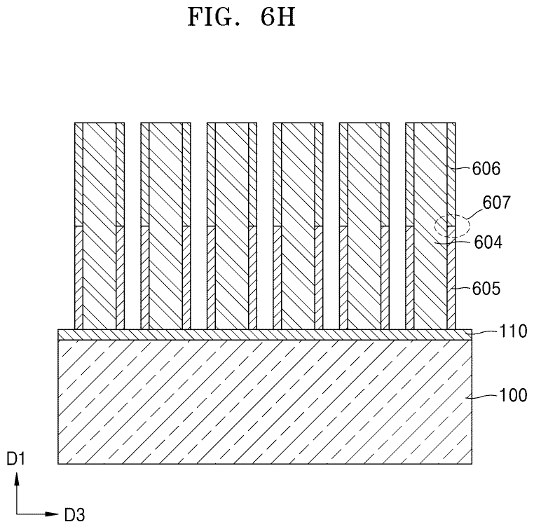

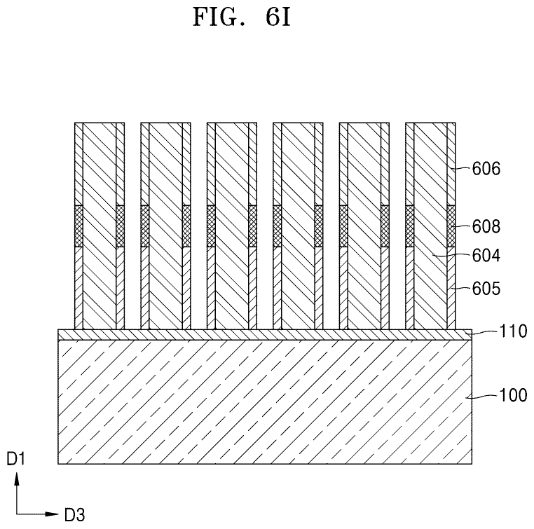

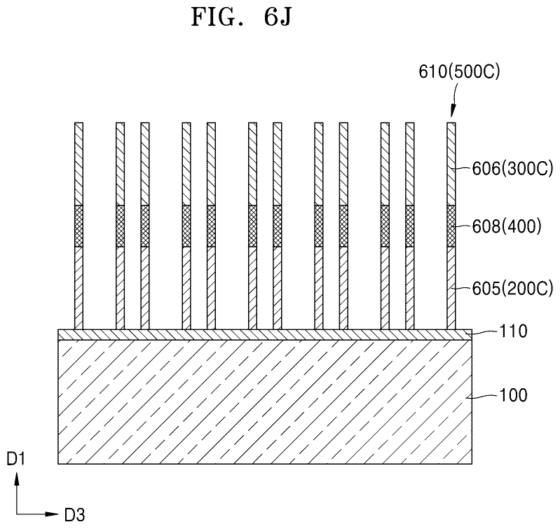

FIGS. 6A to 6J are each a diagram illustrating an example of a manufacturing method of the vertical channel structure 500C. FIGS. 6A to 6J illustrate a method of forming the vertical channel structure 500C including the first vertical channel 200C and the second vertical channel 300C which are vertically stacked, with the spacer 400 of FIG. 2 arranged therebetween. Referring to FIGS. 6A to 6J, a method of forming a vertical channel structure according to some example embodiments may include forming a first channel material layer 605 having a sheet shape by growing a first channel material on the substrate 100 in the vertical direction, e.g., the first direction D1, reducing the height of the first channel material layer 605 by etching the first channel material layer 605, forming a second channel material layer 606 having a sheet shape by growing a second channel material in the vertical direction, e.g., the first direction D1 from an upper portion of the first channel material layer 605, and forming an oxide layer 608 by oxidizing an interface area of the first channel material layer 605 and the second channel material layer 606.

In some example embodiments, the forming of the first channel material layer 605 may include forming a supporter 604 extending in the first direction D1 on the substrate 100 and growing the first channel material in the first direction D1 along a lateral surface of the supporter 604. In some example embodiments, the forming of the second channel material layer 606 may include growing the second channel material in the first direction D1 from the upper portion of the first channel material layer 605 along a lateral surface of the supporter 604. The oxide layer 608 may include an oxide of the first channel material and the second channel material. The first channel material and the second channel material may be identical to each other. The first channel material and the second channel material may include the same TMD material. The oxide layer 608 may include a transition metal oxide. The first channel material and the second channel material may be polysilicon. The oxide layer 608 may include a silicon oxide.

Hereinafter, various example embodiments of a manufacturing method of the vertical channel structure 500C are described. The manufacturing method according to some example embodiments may include forming the supporter 604 extending in the vertical direction, e.g., the first direction D1 on the substrate 100 and growing the channel material in the first direction D1 along the lateral surface of the supporter 604. To this end, the supporter 604 may be formed on the substrate 100.

Referring to FIG. 6A, the substrate 100 may be prepared or provisioned. The substrate 100 may be, for example, an insulating substrate. In this case, the insulating layer 110 may be omitted. The substrate 100 may be or may include a semiconductor substrate, for example, a semiconductor substrate including one or more of Si, Ge, SiGe, or group III-V semiconductor materials. In this case, the insulating layer 110 may be arranged on the surface of the substrate 100. The substrate 100 may be or may include a silicon substrate on which the insulating layer 110 including a silicon oxide is formed. A pattern layer 601 may be formed on an upper surface of the insulating layer 110. The pattern layer 601 may include, for example, a spin-on hardmask (SOH) and in some cases may include silicon oxide. A mask layer 602 having a plurality of openings 603a may be formed on an upper surface of the pattern layer 601. The mask layer 602 may include, for example, SiON. The mask layer 602 may be formed by, for example, a photolithography method. The pattern layer 601 may be etched through the plurality of openings 603a. Then, a plurality of slots 603 may be formed in the pattern layer 601 as illustrated in FIG. 6B. The etching process may be or may include, for example, a wet etching process and/or a dry etching process; example embodiments are not limited thereto. The etching process may stop on the insulating layer 110, in some cases. As illustrated in FIG. 6C, a plurality of supporters 604 may be formed inside the slots 603 by, for example, an atomic layer deposition (ALD) method. The supporter 604 may include an oxide, for example, SiO2. The oxide may also be formed on the upper surface of the mask layer 602. For example, an oxide 604a formed on the upper surface of the mask layer 602 may be removed by, for example, a dry etching process such as an etch-back process and/or by a chemical mechanical planarization (CMP) process. By doing so, as illustrated in FIG. 6D, the plurality of supporters 604 filling the insides of the plurality of slots 603 may be formed. The mask layer 602 and the pattern layer 601 may be removed by an etching process. Then, as illustrated in FIG. 6E, the plurality of supporters 604 extending in the vertical direction may be left on the substrate 100.

Through an ALD method, the first channel material layer 605 may be formed by growing (conformally growing) the first channel material in the first direction D1 from the surface of the substrate 100 along the lateral surface of the plurality of supporters 604 as illustrated in FIG. 6F. This process may be performed by, for example, the ALD process. The first channel material may be or may include, for example, a TMD material. The TMD material may include, for example, one transition metal from among Mo, W, Nb, V, Ta, Ti, Zr, Hf, Tc, and Re and one chalcogen element from among S, Se, and Te. The TMD material may be represented by, for example, MX₂ where M represents a transition metal, and X represents a chalcogen element. For example, M may be Mo, W, Nb, V, Ta, Ti, Zr, Hf, Tc, Re, etc., and X may be S, Se, T, etc. Accordingly, the TMD material may include at least one of MoS2, MoSe2, MoTe2, WS2, WSe2, WTe2, ZrS2, ZrSe2, HfS2, HfSe2, NbSe2, ReSe2, etc. As described above, the TMD material may include a material that is not represented by MX₂, for example, CuS, and may be a chalcogenide material including a non-transition metal. The first channel material may be a polysilicon. In some example embodiments, a TMD material may be used as the first channel material.

Next, lowing of the height of the first channel material layer 605 may be performed. For example, the upper portion of the first channel material layer 605 may be etched, e.g., with a wet and/or dry etching process. The etching process may be a timed etching process; however, example embodiments are not limited thereto. Then, as illustrated in FIG. 6G, the upper portion of the first channel material layer 605 may be removed, and the height of the first channel material layer 605 may be reduced. An upper portion 604b of the supporter 604 may be exposed by the decrement of the height of the first channel material layer 605.

Next, forming of the second channel material layer 606 may be performed. As illustrated in FIG. 6H, the second channel material layer 606 may be formed by growing the second channel material in the first direction D1 from the upper portion of the first channel material layer 605 along the lateral surface of the upper portion 604b of the supporter 604. The second channel material may be identical to or different from the first channel material. The second channel material may include the same TMD material as the first channel material or may be or may include a different TMD material from the first channel material. In some example embodiments, the second channel material include the same TMD material as the first channel material.

Next, forming the oxide layer 608 may be performed. There may be a defect such as a vacancy in an interface area 607 adjacent to an interface between the first channel material layer 605 and the second channel material layer 606. As described above, as a TMD material lacks a dangling bond, it may be difficult to deposit a dielectric material forming the spacer 400 on the TMD material. However, in the case of a TMD material, a dielectric layer may be formed in a defect, by oxidizing the interface area 607 including a defect, a spacer may be formed. Accordingly, by providing oxygen to the interface area 607 through, for example, the ALD process, a channel material layer 605 and a channel material layer 606 of the interface area 607 may be oxidized. By doing so, as illustrated in FIG. 6I, the oxide layer 608 may be formed between the channel material layer 605 and the channel material layer 606. The oxide layer 608 may include an oxide of the first and second channel materials. When the first and second channel materials are or include a TMD material, the oxide layer 608 may include a transition metal oxide, such as a transition metal oxide of the first channel material and a transition metal oxide of the second channel material. An oxidation rate of the first channel material may be the same as, or less than, or greater than, an oxidation rate of the second channel material.

The plurality of supporters 604 may be removed by, for example, the wet etching process. By doing so, as illustrated in FIG. 6J, a plurality of vertical channel structures 610 in which the first channel material layer 605, the oxide layer 608, and the second channel material layer 606 are sequentially stacked may be formed on the substrate 100. The first channel material layer 605, the oxide layer 608, and the second channel material layer 606 may respectively correspond to the first vertical channel 200C, the spacer 400, and the second vertical channel 300C illustrated in FIG. 5. The vertical channel structure 610 may correspond to the vertical channel structure 500C illustrated in FIGS. 1 to 5.

Although it is not shown in the drawings, the vertical channel transistor structure 500 or the vertical channel transistor array 500AR illustrated in FIGS. 1 to 4 may be formed by forming the first and second source electrodes 200S and 300S, the first and second drain electrodes 200D and 300D, and the first and second gate electrodes 200G and 300G. A process of forming electrodes may be performed by widely known processes. In addition, in the state illustrated in FIG. 6j, after forming the vertical transistor array 500AR-1 by forming the electrodes, the isolation layer 120 may be covered by the vertical transistor array 500AR-1, and then by performing the aforementioned process thereon, the vertical transistor array 500AR-2 may be formed. By doing so, example embodiments of the semiconductor device 1 illustrated in FIG. 5 may be implemented.

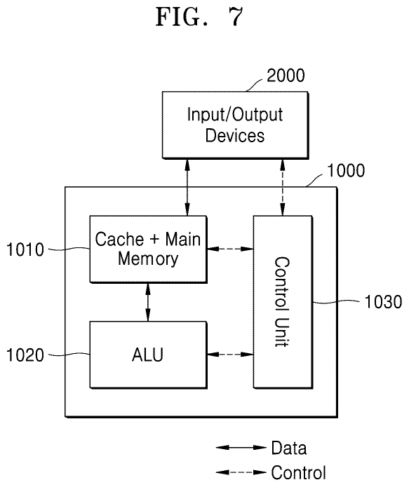

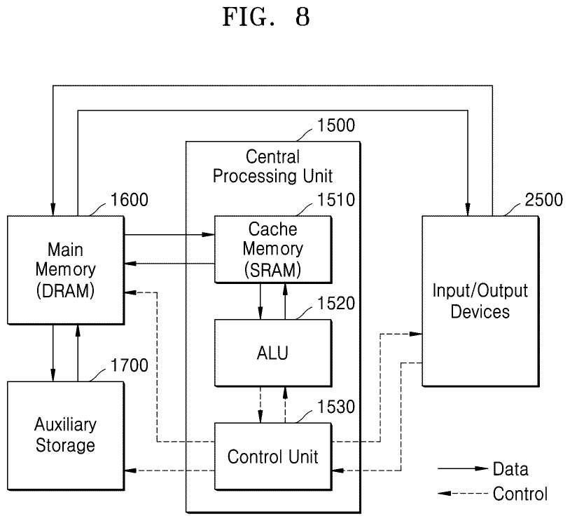

The semiconductor device 1 according to various example embodiments described above may be used for storage such as for temporary storage of data in various electronic apparatuses. FIGS. 7 and 8 are each a conceptual diagram schematically illustrating a device architecture applicable to an electronic apparatus according to some example embodiments.

Referring to FIG. 7, a device architecture 1000 may include a memory unit 1010, an arithmetic logic unit (ALU) 1020, and a control unit 1030. The memory unit 1010, the ALU 1020, and the control unit 1030 may be electrically connected. For example, the device architecture 1000 may be implemented as a single chip including the memory unit 1010, the ALU 1020, and the control unit 1030. Specifically, the memory unit 1010, the ALU 1020, and the control unit 1030 may be interconnected by a metal line on an on-chip and communicate directly with each other. The memory unit 1010, the ALU 1020, and the control unit 1030 may be integrated on one substrate in a monolithic manner and constitute a single chip. An input/output devices 2000 may be connected to the device architecture 1000. The memory unit 1010 may include both of a main memory and a cache memory. The main memory may include the semiconductor device 1 described above.

Referring to FIG. 8, a cache memory 1510, an ALU 1520, and a control unit 1530 may constitute a central processing unit 1500, and the cache memory 1510 may include static random access memory (SRAM). A main memory 1600 and an auxiliary storage 1700 may be provided separately from the CPU 1500. The main memory 1600 may include the semiconductor device 1 described above. In some cases, the device architecture may be implemented in a form in which computing unit elements and memory unit elements are adjacent to each other on a single chip without separating sub-units.

According to various example embodiments of the semiconductor device described above, by employing a vertical channel structure, the integration degree of unit elements may be improved.

Alternatively or additionally according to various example embodiments of the manufacturing method of the vertical channel structure described above, the vertical channel structure may be easily manufactured by using a depositable channel material.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that variously described example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
a first vertical channel having a sheet shape, the sheet shape of the first vertical channel extending from the substrate in a first direction perpendicular to a surface of the substrate;
a spacer at an end of the first vertical channel in the first direction; and
a second vertical channel aligned with the first vertical channel on the spacer and having a sheet shape, the sheet shape of the second vertical channel extending in the first direction.

2. The semiconductor device of claim 1, wherein the spacer includes an oxide of a material of the first vertical channel.

3. The semiconductor device of claim 1, wherein the first vertical channel and the second vertical channel each include a same or different transition metal dichalcogenide (TMD) material.

4. The semiconductor device of claim 3, wherein the TMD material in the first vertical channel or the TMD material in the second vertical channel independently includes at least one selected from MoS2, MoSe2, MoTe2, WS2, WSe2, WTe2, ZrS2, ZrSe2, HfS2, HfSe2, NbSe2, and ReSe2.

5. The semiconductor device of claim 4, wherein the spacer includes a transition metal oxide.

6. The semiconductor device of claim 1, wherein the first vertical channel and the second vertical channel each include polysilicon.

7. The semiconductor device of claim 6, wherein the spacer includes a silicon oxide.

8. The semiconductor device of claim 1, wherein the first vertical channel and the second vertical channel have different conductivity types from each other.

9. The semiconductor device of claim 1, wherein the first vertical channel and the second vertical channel have a same conductivity type.

10. The semiconductor device of claim 1, further comprising:
a first source electrode and a first drain electrode which are electrically connected to the first vertical channel;
a first gate electrode facing the first vertical channel with a first gate insulating film arranged therebetween;
a second source electrode and a second drain electrode which are electrically connected to the second vertical channel; and
a second gate electrode facing the second vertical channel with a second gate insulating film arranged therebetween.

11. The semiconductor device of claim 1, further comprising:
a vertical channel transistor array including a plurality of first vertical channels and a plurality of second vertical channels arranged in a two-dimensional (2D) manner on a plane perpendicular to the first direction.

12. The semiconductor device of claim 11, wherein the vertical channel transistor array includes a plurality of vertical channel transistor arrays stacked in the first direction with an isolation layer arranged therebetween.

13. A manufacturing method of a vertical channel structure, the manufacturing method comprising:
forming a first channel material layer having a sheet shape by growing a first channel material in a vertical direction on a substrate;
reducing a height of the first channel material layer by etching the first channel material layer;
forming a second channel material layer having a sheet shape by growing a second channel material in the vertical direction from an upper portion of the first channel material layer; and
forming an oxide layer by oxidizing an interface area of the first channel material layer and the second channel material layer.

14. The manufacturing method of claim 13, wherein the forming of the first channel material layer comprises:
forming a supporter extending in the vertical direction on the substrate; and
growing the first channel material in the vertical direction along a lateral surface of the supporter.

15. The manufacturing method of claim 13, wherein the forming of the second channel material layer comprises growing the second channel material in the vertical direction from the upper portion of the first channel material layer along a lateral surface of a supporter.

16. The manufacturing method of claim 13, wherein the oxide layer includes an oxide of the first channel material and the second channel material.

17. The manufacturing method of claim 13, wherein
the first channel material and the second channel material each include a transition metal dichalcogenide (TMD) material, and
the oxide layer includes a transition metal oxide.

18. The manufacturing method of claim 13, wherein the first channel material and the second channel material are polysilicon, and
the oxide layer includes a silicon oxide.
